(19) United States
(12) Patent Application Publication
(10) Pub. No.: US 2026/0231534 A1
(43) Pub. Date: Aug. 6, 2026

(54) FIELD-EFFECT TRANSISTOR WITH INTEGRATED SHUNT RC NETWORK

(71) Applicant: MACOM Technology Solutions Holdings, Inc., Lowell, MA (US)

(72) Inventors: Kelly Elizabeth Doherty, Chapel Hill, NC (US); Simon Maurice Wood, Morgan Hill, CA (US)

(21) Appl. No.: 19/047,097

(22) Filed: Feb. 6, 2025

(51) Int. Cl. H10D 89/60

(52) U.S. Cl. CPC H10D 89/819

(57) ABSTRACT

A transistor circuit includes a field-effect transistor (FET) device including a gate connected to an input terminal of the transistor circuit, a source connected to a reference voltage of the transistor circuit, and a drain connected to an output terminal of the transistor circuit. The transistor circuit further includes a shunt resistor-capacitor (RC) network connected in series between the gate of the FET device and the reference voltage of the transistor circuit, the shunt RC network being integrated on a same die with the FET device.

### FIELD

The present disclosure relates generally to field-effect transistors (FET) devices, and, more particularly, to FET devices having enhanced stability.

### BACKGROUND

For applications such as, but not limited to, lower frequency (e.g., less than about 200 MHz), high-power applications, FET device stability is often difficult to achieve in package. As the gain of the FET device increases, there is generally an increased presence of low-frequency oscillations (e.g., oscillation frequencies much lower than fundamental frequencies of operation of the FET device).

FET devices are often mounted on a printed circuit board as this allows the FET devices to be conveniently electrically connected to other circuit elements. Conventionally, low-frequency oscillations have been addressed on the printed circuit board using external (i.e., off-chip) components, such as a separate integrated passive device (IPD). For example, it is known to stabilize the FET device using a series resistance in front of a gate of the FET device to thereby reduce oscillations. However, such stabilization comes at the cost of decreased maximum available gain of the FET device. Furthermore, the use of a separate IPD with the FET device can add significant cost to the overall circuit.

### SUMMARY

The present invention, as manifested in one or more embodiments, provides a packaged high-power FET device that includes an integrated shunt RC network for enhancing stability of the FET device, particularly at lower operating frequencies. By integrating the shunt RC network on the same chip as the FET device, the need for a separate (i.e., off-chip) integrated passive device (IPD) may be avoided. Furthermore, compared to conventional FET device arrangements which require an off-chip IPD to provide stability at certain operating frequencies, embodiments of the present invention present an improved trade-off between stability and performance of the FET device (e.g., increased maximum available gain), for example, by allowing the capacitance in the shunt RC network to be reduced for meeting a prescribed frequency of unconditional stability of the FET device.

In accordance with an embodiment of the present disclosure, a transistor circuit having enhanced stability includes a FET device including a gate connected to an input terminal of the transistor circuit, a source connected to a reference voltage of the transistor circuit, and a drain connected to an output terminal of the transistor circuit. The transistor circuit further includes a shunt RC network connected in series between the gate of the FET device and the reference voltage of the transistor circuit, the shunt RC network being integrated on a same die with the FET device.

In accordance with another embodiment of the present disclosure, an integrated circuit (IC) die includes a FET including a gate configured to receive an input signal provided to the FET, a source connected to a reference voltage through a source via, and a drain configured to present an output signal of the FET. The IC die further includes a shunt RC network connected between the gate of the FET and the reference voltage through the source via.

In accordance with yet another embodiment of the present disclosure, an IC die includes at least one bond pad and a FET including a gate connected to the bond pad, a source connected to a reference voltage through a source via, and a drain. The IC die further includes a shunt RC network connected between the gate of the FET and the reference voltage. The shunt RC network includes a capacitor including a first electrode, a second electrode and a dielectric material between the first and second electrodes, wherein the bond pad forms the first electrode of the capacitor in the shunt RC network.

Techniques of the present inventive concept can provide substantial beneficial technical effects. By way of example only and without limitation, aspects according to embodiments of the present disclosure may provide one or more of the following advantages, among other benefits:
eliminating the need for an integrated passive device or other off-chip components to reduce the presence of low-frequency oscillations;
reducing low-frequency oscillations with less reduction in the maximum available gain of the FET device as compared to conventional devices requiring an integrated passive device or other off-chip components, thereby providing an improved trade-off between device stability and maximum available gain;
integrating an RC network with the FET device to thereby eliminate the need for wire bonding or other connection structures to off-chip components and thereby reduce parasitic inductance and/or capacitance which would otherwise decrease the bandwidth of the FET device;
reducing overall device cost by eliminating the need for additional off-chip components which add manufacturing cost as well as assembly cost.

These and other features and advantages of the present inventive concept will become apparent from the following detailed description of illustrative embodiments thereof, which is to be read in connection with the accompanying drawings.

### BRIEF DESCRIPTION OF THE DRAWINGS

The accompanying drawings, which are included to provide a further understanding of the invention and are incorporated in and constitute a part of this application, are presented by way of example only and without limitation, wherein like reference numerals (when used) indicate corresponding elements throughout the several views, and wherein:

FIG. 1 is a schematic top plan view depicting the interior of an illustrative IC package comprising a substrate including a plurality of active dies provided thereon;

FIG. 2A is a circuit diagram depicting an example FET circuit comprising a FET device integrated with a shunt RC network, according to one or more embodiments of the inventive concept;

FIG. 2B is a schematic top plan view depicting at least a portion of an illustrative an IC die including the FET circuit shown in FIG. 2A, according to one or more embodiments of the inventive concept;

FIG. 3 is a schematic top plan view depicting an enlarged region, A, of the IC die shown in FIG. 2B, according to one or more embodiments of the inventive concept;

FIGS. 4A, 5A, 5B, 6A, 7A, 7B, 8A, 9A and 9B are graphs presenting waveforms depicting the K factor (i.e., a stability factor) of a FET device, with and without an integrated shunt RC network, as a function of frequency for three different illustrative fabrication technologies, according to example embodiments of the inventive concept; and

FIGS. 4B, 6B and 8B are graphs presenting waveforms depicting maximum available gain of the FET device including an integrated shunt RC network as a function of frequency for the different illustrative fabrication technologies, according to example embodiments of the inventive concept.

It is to be appreciated that elements in the figures may be illustrated for simplicity and clarity. Common but well-understood elements that may be useful or necessary in a commercially feasible embodiment are not necessarily shown in order to facilitate a less hindered view of the illustrated embodiments.

### DETAILED DESCRIPTION

Principles of the present inventive concept, as manifested in one or more embodiments, may be described herein in the context of a high-power FET device, and more specifically to embodiments of a FET device that have an integrated resistor-capacitor (RC) network configured to provide enhanced stability and performance, particularly FET devices operating at lower frequencies (e.g., less than about 200 MHz) and higher power (e.g., greater than about 25 watts), which may be suitable for use with various device fabrication technologies. It is to be appreciated, however, that the inventive concept is not limited to the specific devices, circuits, systems and/or methods illustratively shown and described herein, and moreover is not limited to FET devices operating at lower frequencies and/or higher power; that is, any FET device exhibiting stability issues, regardless of power capability or operating frequency, can benefit from aspects of the inventive concept. Rather, it will become apparent to those skilled in the art given the teachings herein that numerous modifications to the embodiments shown are contemplated and are within the scope of embodiments of the claimed invention. That is, no limitations with respect to the embodiments shown and described herein are intended or should be inferred.

Although the overall fabrication method and structures formed thereby as described herein are entirely novel, certain individual processing steps required to implement a portion or portions of the method(s) according to one or more embodiments of the inventive concept may utilize conventional semiconductor fabrication techniques and/or conventional semiconductor fabrication tooling. These techniques and tooling will already be familiar to one having ordinary skill in the relevant art. Moreover, many of the processing steps and tooling used to fabricate semiconductor devices are also described in a number of readily available publications, including, for example: P. H. Holloway et al., Handbook of Compound Semiconductors: Growth, Processing, Characterization, and Devices, Cambridge University Press, 2008; and R. K. Willardson et al., Processing and Properties of Compound Semiconductors, Academic Press, 2001, which are incorporated by reference herein in their entirety. It is emphasized that while some individual processing steps may be set forth herein, those steps are merely illustrative and one skilled in the art may be familiar with several equally suitable alternatives that would also fall within the scope of the present disclosure.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are contemplated. For example, a region illustrated or described as square or rectangular may have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale.

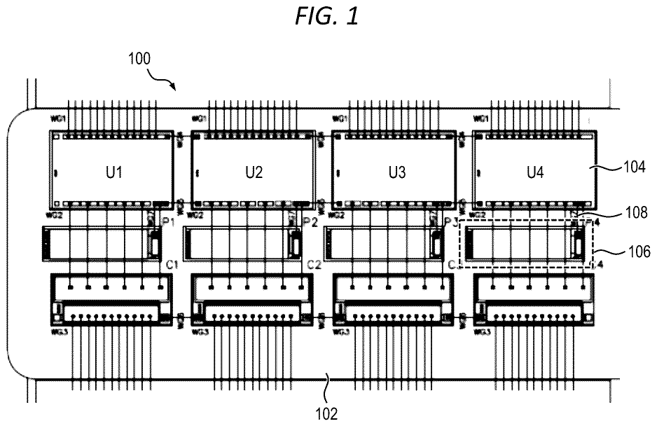

FIG. 1 is a schematic top plan view depicting the interior of an illustrative IC package 100, which may comprise a substrate (e.g., laminate or printed circuit board (PCB)) 102 including a plurality of active dies U1 through U4 provided thereon. Each active die U1 through U4 may be a Group III nitride based die including at least one FET device 104. As used herein, the term “Group III nitride” refers to those semiconducting compounds formed between nitrogen and the elements in Group III of the periodic table, usually aluminum (Al), gallium (Ga), and/or indium (In). The term also refers to ternary and quaternary compounds, such as AlGaN and AlInGaN. These compounds have empirical formulas in which one mole of nitrogen is combined with a total of one mole of the Group III elements. The FET device may comprise, for example, a High Electron Mobility Transistor (“HEMT”) device. The HEMT device may, for example, be used to implement an RF transistor amplifier. In some example embodiments, the FET device may be a Group III-nitride based HEMT RF transistor amplifier that is implemented in gallium nitride (GaN) based semiconductor epitaxial layers that are formed on a silicon carbide (SiC) substrate, although embodiments of the present invention are not limited thereto.

As previously stated, in order to reduce oscillations that may occur, particularly at lower frequencies of operation (e.g., less than about 200 MHz), each FET device 104 may be electrically connected to a corresponding integrated passive device (IPD) 106 configured as an off-chip shunt RC network. The IPD 106 may be fabricated on a separate gallium arsenide (GaAs) die that is connected to the corresponding FET device 104 using wire bonds 108.

While this arrangement of using a separate (i.e., off-chip) IPD 106 connected to the FET device 104 on a corresponding one of the active dies U1 through U4 on the substrate 102 may reduce low frequency oscillations, thereby improving the stability of the FET device 104, it does so at the cost of decreasing maximum available gain of the FET device 104. The need for a separate IPD 106 also adds to the overall cost of the device. Furthermore, the use of wire bonds 108 may increase the presence of parasitic elements (e.g., inductance) which can undesirably effect high-frequency performance of the FET device 104, in addition to increasing fabrication costs and complexity.

Pursuant to embodiments of the present inventive concept, a FET device is provided that includes a shunt RC network integrated with the FET device on the same die and configured to reduce the presence of low frequency oscillations in the FET device, thereby enhancing the stability of the FET device without the need for a separate IPD. While the integrated shunt RC network may still reduce the maximum available gain of the FET device, integrating the shunt RC network on the same die as the FET device may allow a designer to achieve a higher degree of control over the cutoff frequency of the shunt RC network, due at least in part to the elimination of bond wires and/or other parasitic elements that are introduced using a separate off-chip IPD.

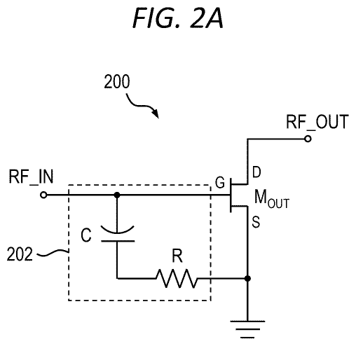

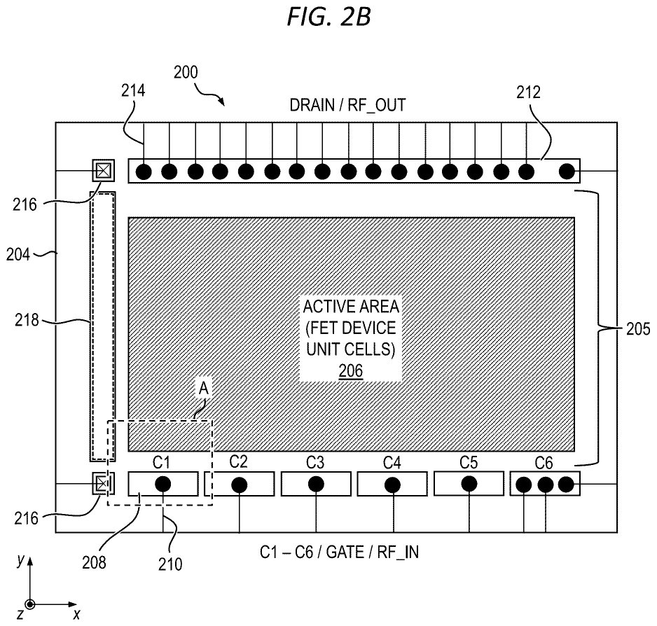

FIG. 2A is a circuit diagram depicting an example FET circuit 200 that comprises a FET device (e.g., a HEMT RF transistor amplifier) and a shunt RC network that is with the FET device, according to one or more embodiments of the inventive concept. FIG. 2B is a schematic top plan view depicting at least a portion of an illustrative die including the FET circuit 200 shown in FIG. 2A, according to one or more embodiments. Referring to FIG. 2A, the FET circuit 200 includes a FET device, M_{OUT}, which may be an n-channel FET (NFET), and a shunt RC network 202 connected to the FET device M_{OUT} and integrated in the same die as the FET device M_{OUT}. The term “connected” (or “connecting,” or like terms such as “contact” or “contacting”), as may be used herein, is intended to refer to a physical and/or electrical connection between two or more elements, and may include other intervening elements unless the context indicates otherwise. As used herein, the term “and/or” includes any and all combinations of one or more of the associated listed items.

In one or more embodiments, the die in which the FET device M_{OUT} and the shunt RC network 202 are integrated may be a Group III nitride based die, although the present disclosure is not limited thereto. A Group III nitride based die refers to a die that includes at least one Group III nitride semiconductor layer (e.g., GaN). A gate (G) of the FET device M_{OUT} may connected to a radio frequency (RF) input, RF_IN, of the FET circuit 200 (e.g., an RF input bond pad). A drain (D) of the FET device M_{OUT} may be connected to an RF output, RF_OUT, of the FET circuit 200 (e.g., an RF output bond pad). In one or more embodiments, a source(S) of the FET device M_{OUT} may be connected to ground or another voltage source (e.g., VSS).

The shunt RC network 202 at the gate of the FET device M_{OUT} acts as a low-pass filter. The shunt RC network 202 may include a capacitor C and a resistor R connected together in series between the gate and the source of the FET device M_{OUT}. In one or more embodiments, a first terminal (i.e., electrode or plate) of the capacitor C is connected to the gate of the FET device M_{OUT}, a second terminal of the capacitor C is connected to a first terminal of the resistor R, and a second terminal of the resistor R is connected to the source of the FET device M_{OUT}. It is to be appreciated that the connection order of the resistor R and capacitor C in the shunt RC network 202 may be reversed; that is, the resistor R may be connected to the gate of the FET device M_{OUT} and the capacitor C may be connected to the source of the FET device M_{OUT} in some embodiments.

In some embodiments, the capacitor C in the shunt RC network 202 may comprise a plurality of capacitor elements (e.g., C1 through C6 shown in FIG. 2B, each capacitor element C1 through C6 being associated with a corresponding unit cell FET device). Likewise, although not explicitly shown, the resistor R in the shunt RC network 202 may be formed using a plurality of resistor elements. This is particularly beneficial when the FET device M_{OUT} comprises a plurality of unit cells, with each unit cell including a corresponding shunt RC network 202. The plurality of resistor elements need not be connected adjacent to one another, but rather the resistor elements may be interspersed with capacitor elements therebetween, or vice versa. The value of resistance used for the resistor R and the value of capacitance used for the capacitor C will depend on the intended cutoff frequency for which the shunt RC network 202 is configured.

Referring to FIG. 2B, the FET circuit 200 may be formed in/on an integrated circuit (IC) die 204 that comprises, for example, a Group III nitride semiconductor layer structure 205 (i.e., one or more semiconductor layers that include at least one Group III nitride semiconductor layer), although embodiments are not limited thereto. The semiconductor layer structure 205 includes an active area 206, which may be a region of the semiconductor layer structure 205 that is doped with impurities (e.g., p-type and/or n-type impurities) of a prescribed doping concentration level. The active area 206 may be formed, for example, using an epitaxial growth process. The FET device (M_{OUT} in FIG. 2A) is formed in the active area 206. One or more first bond pads 208 may be provided along a periphery of the semiconductor layer structure 205. The first bond pads 208 may be electrically connected to the gate of a FET device (M_{OUT} in FIG. 2A) included in the FET circuit 200. Where the FET device included in the FET circuit 200 comprises a plurality of unit cells, each unit cell gate may be connected to a corresponding one of the first bond pads 208.

The capacitor (C in FIG. 2A) in the shunt RC network may comprise a plurality of capacitor elements, C1 through C6, where in this example there are six unit cells in the FET circuit 200, each capacitor being connected to a corresponding one of the FET unit cells. Each of the capacitors C1 through C6 may be provided under a corresponding one of the first bond pads 208. The first bond pads 208 may be electrically connected to one another, for example using resistors or other conductive elements, to form an RF input terminal RF_IN of the FET circuit 200. External access to the gate of the FET device may be provided using first wire bonds 210 or other connection means (e.g., solder balls, etc.) connected to the first bond pads 208. At least one second bond pad 212 may be connected to the drain of the FET device, which may form an RF output terminal RF_OUT of the FET circuit 200. External access to the drain of the FET device may be provided using wire bonds 214 or other connection means (e.g., solder balls, etc.) connected to the second bond pad 212. In some embodiments, one or more tie pads 216 may be optionally provided to stitch together multiple die for providing multi-die stabilization. Optionally, where sufficient space is unavailable under the first bond pads 208 for forming a capacitor with sufficient capacitance to meet prescribed frequency stabilization requirements, an additional capacitor 218 may be provided in a different location of the die 204, such as, but not limited to, on a periphery of the die 204 between the tie pads 216.

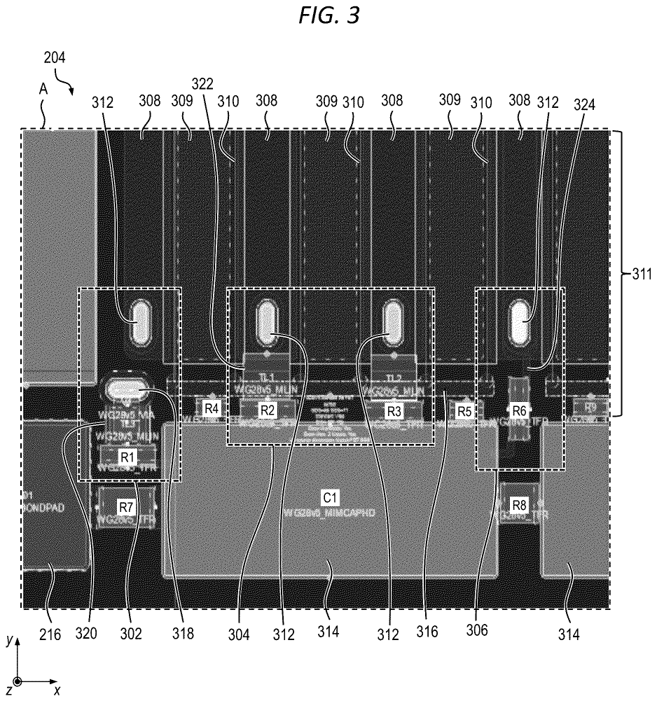

The shunt RC network may be integrated with the FET device in multiple ways, depending on the particular layout of the die 204 and the IC fabrication technology used, among other factors. By way of example only and without limitation, FIG. 3 is a schematic top plan view depicting an enlarged region, A, of the die 204 comprising the FET device and integrated shunt RC network shown in FIG. 2B, according to embodiments of the inventive concept. In this example, three different layout options are shown for integrating the shunt RC network with the FET device in a given one of the FET unit cells. However, it is to be appreciated that although only three layout options are shown for economy of description, embodiments of the inventive concept are not limited thereto. Rather, it will become apparent to those skilled in the art given the teachings herein that there are many options for integrating the shunt RC network with the FET device that are within the scope of the inventive concept.

Although not shown in explicit detail in the top plan view of FIG. 3, the FET device may be formed in a “semiconductor layer structure” which may include one or more semiconductor layers/regions. As will be described in further detail below, a source region and a drain region of the FET device are formed in the semiconductor layer structure that are separated by a channel region of the FET device. A gate electrode (which may act as the gate terminal or be electrically connected to the gate terminal) is disposed adjacent to the channel region and separated from the channel region by a thin layer of insulating material (e.g., oxide), generally referred to as a gate oxide layer. Other non-oxide gate dielectric layers may be used in certain applications in place of the gate oxide layer. It will be appreciated that the techniques according to embodiments of the present invention that are described herein are equally applicable to devices having gate dielectric layers formed with materials other than oxides. The IC die 204 includes the semiconductor layer structure and one or more metallization layers used to electrically connect the various circuit elements.

Referring to FIG. 3, a first area 302 of region A of the IC die 204 depicts a first layout option for integrating the shunt RC network with the FET device, a second area 304 of the die 204 depicts a second layout option, and a third area 306 of the die 204 depicts a third layout option. These layout options may be employed separately (e.g., as alternative configurations), or two or more layout options may be used in combination with one another (or with other layout configurations not explicitly shown in FIG. 3). The selection of which layout option(s) to use for the shunt RC network may be based on the available space on the die 204, the desired frequency of unconditional stabilization of the FET device, and the IC fabrication technology, among other factors.

The die 204 includes a plurality of source regions 308 and drain regions 309 formed in an active region 311 of the FET device. Each of the source regions 308 and drain regions 309 may extend in a first direction (e.g., y-axis direction), parallel to a surface of the semiconductor layer structure in which the source and drain regions 308, 309 are formed. The source and drain regions 308, 309 are alternatively arranged in a second direction (e.g., x-axis direction) parallel to the surface of the semiconductor layer structure and intersecting the first direction, so that each source region 308 is adjacent to a drain region 309 in the second direction. The die 204 further includes a plurality of gate fingers 310 extending over the active region 311 in the first direction, with each gate finger 310 disposed between a pair of adjacent source and drain regions 308, 309. Source vias 312 that extend through the semiconductor layer structure are provided in the active region 311 for electrically connecting the respective source regions 308 to ground, or an alternative reference voltage (e.g., VSS). The source vias 312 may electrically connect the source regions 308 (which are metal regions formed on a front side of the semiconductor layer structure) to a metal layer on the back side of the semiconductor layer structure that is often referred to as a backside metal layer. The backside metal layer is typically connected to a reference voltage such as ground. Respective portions of the active region 311 under the gate fingers 310, between adjacent source and drain regions 308, 309, form channel regions of the FET device. In this example embodiment, the FET device may include a plurality of unit cell transistors, with each gate of a unit cell transistor comprising a plurality of gate fingers 310.

The die 204 further includes a first bond pad 314, which may be one of the plurality of first bond pads 208 shown in FIG. 2B forming the RF input terminal RF_IN of the FET circuit 200 (see FIGS. 2A and 2B). The plurality of gate fingers 310 may be electrically connected to the first bond pad 314, either directly or using a common gate bus 316 interposed between the gate fingers 310 and the first bond pad 314. Although six gate fingers 310 are shown connected to the first bond pad 314 for each unit cell transistor, embodiments are not limited thereto. For example, a wider first bond pad 314 may support a larger number of gate fingers (e.g., seven or more), or a narrower first bond pad 314 may support a smaller number of gate fingers (e.g., five or less). The number of first bond pads 314 may depend on dimensions of a periphery of the die 204.

One or more series gate resistors and/or odd mode resistors may be implemented on the die 204. These resistors may be used to stabilize feedback loops within the gate fingers and drain regions of the FET device. In high power devices, the gate fingers may have long gate widths in order to increase the gate periphery of the device, which results in long feedback loops. Because these high power transistors have large transconductance values, the feedback loops may be prone to instability. In particular, the feedback loops may generate an unwanted signal which may be in or out of the frequency band of operation of the transistor. In either case, the generation of such a signal may be problematic, and may render the transistor unusable. The instability of the feedback loops tends to increase with the length of the feedback loop. The series gate resistors and odd-mode resistors are additional resistances that are included in the FET device (i.e., they are different than the resistor(s) of the shunt RC network) and generally do not affect the characteristics of the shunt RC network.

The gate bus 316, when used, may be connected to the first bond pad 314 using one or more resistors and/or other conductive elements (e.g., transmission lines). In some embodiments, series gate resistors R4 and R5 may be used to electrically connect the gate bus 316 to the first bond pad 314. The gate bus 316 may be configured to provide additional space for placing the shunt RC network, as may be used, for example, in conjunction with the second layout option shown in the second area 304, as will be described in further detail below. These resistors R4, R5 may be connected in series between the gate of the FET device and the RF input at the first bond pad 314, and do not have a significant effect on the characteristics of the shunt RC network.

The IC die 204 may further include resistors R7 and R8, which may be odd mode stability resistors that connect the first bond pads 314 to one another for electrically connecting all of the unit cells of the FET device together and/or to electrically connect one FET device to another FET device inside a given IC package.

In the first area 302, the first layout option for the shunt RC network may include a single shunt resistor, R1, disposed between adjacent first bond pads 314, or between the first bond pad 314 and the tie pad 216 (as shown in FIG. 3). In one or more embodiments, a first terminal of the shunt resistor R1 may be electrically connected to ground using an independent via 318 to a backside metal layer. The independent via 318 may be a via disposed outside of (i.e., spaced apart from) the source region 308 of the FET device. The first terminal of the shunt resistor R1 may be connected to the independent via 318 using a first transmission line 320 or other connection element. The first transmission line 320 may comprise, for example, a metal conductor. In other embodiments, the first terminal of the shunt resistor R1 may be electrically connected to ground through at least one of the source vias 312 (e.g., a source via 312 proximate the shunt resistor R1). The first terminal of the shunt resistor R1 may be directly connected to ground through a corresponding via, or it may be indirectly connected to ground through a series capacitor. For example, the first terminal of the shunt resistor R1 may be connected to a first terminal of a series capacitor (not explicitly shown), which may be disposed under the first transmission line 320, and a second terminal of the series capacitor may be connected to ground through the independent via 318 and/or the source via 312; the first transmission line 320 may form one of the plates of the series capacitor. A second terminal of the shunt resistor R1 may be connected to a capacitor, C1, of the shunt RC network.

In the embodiment shown in FIG. 3, the capacitor C1 may be disposed under the first bond pad 314. For example, the first bond pad 314 may form a first plate of the capacitor C1, a second plate of the capacitor C1 may be formed under the first bond pad 314 using a metal layer different from the metal layer forming the first bond pad 314. An insulating layer (e.g., dielectric material) may be provided between the first bond pad 314 and the second plate of the capacitor C1 to electrically insulate the first and second plates of the capacitor C1. Formed in this manner, the capacitor C1 may be a metal-insulator-metal (MIM) capacitor, although embodiments are not limited thereto. The second terminal of the shunt resistor R1 may be electrically connected to the second plate of the capacitor C1 using a metal conductor or other connection element. Depending on the value of capacitance required for the capacitor C1, the second plate of the capacitor C1 may be smaller in area (viewed in plan view) relative to an area of the first bond pad 314.

In some embodiments, assuming sufficient space is available between adjacent first bond pads 314, an area of the first bond pad 314 may be enlarged (e.g., by extending the first bond pad 314 in the second direction (x-axis direction)), along with enlarging an area of the underlying second plate of the capacitor C1, to provide a higher capacitance value for the capacitor C1 to meet lower frequency stabilization requirements. If sufficient space is unavailable between adjacent first bond pads 314, an additional capacitor (e.g., capacitor 218 in FIG. 2B) may be optionally provided in a different location on the IC die 204 that is configured to meet prescribed frequency stability parameters of the FET device. Additionally or alternatively, capacitor C1 could be implemented as a monolithically integrated multi-layer metal-insulator-metal capacitor that includes at least three metal layers and two dielectric layers. Examples of such monolithically integrated multi-layer metal-insulator-metal capacitors are disclosed in U.S. Pat. No. 12,191,821, the entire contents of which is incorporated herein by reference.

In the second area 304, the second layout option for the shunt RC network may provide a distributed configuration of the shunt resistor (resistor R in FIG. 2A). For example, the shunt resistor in the second layout option may include two resistors, R2 and R3. A first terminal of each of the shunt resistors R2, R3 may be electrically connected to the capacitor C1 (e.g., the second plate of the capacitor C1 underlying the first bond pad 314) and a second terminal of each of the shunt resistors R2, R3 may be electrically connected to ground through a corresponding one of the source vias 312 using a second transmission line 322 or other connection element.

The second transmission lines 322 connecting the respective shunt resistors R2, R3 to the corresponding source vias 312 may be routed under (or over) the gate bus 316. In order to achieve this, the second transmission lines 322 may be formed in a different metal layer relative to the metal layer used to form the gate bus 316 to thereby prevent electrically shorting the second transmission lines 322 to the gate bus 316. The use of the gate bus 316, rather than directly connecting the gate fingers 310 to the first bond pad 314, provides additional space between the active region 311 and the first bond pad 314 for placing the shunt resistors R2, R3 when using the second layout option.

In the third area 306, the third layout option for the shunt RC network may include at least one shunt resistor, R6, configured between the first bond pads 314 of adjacent unit cells. A first terminal of the shunt resistor R6 may be electrically connected to the capacitor C1 (e.g., the second plate of the capacitor C1 underlying the first bond pad 314), and a second terminal of the shunt resistor R6 may be electrically connected to a corresponding one of the source vias 312, for example using a metal conductor 324 or other connection element. Assuming there is sufficient space between the adjacent first bond pads 314, the shunt resistor R6 may be placed between respective segments of the gate bus 316 corresponding to adjacent unit cells. This arrangement allows the shunt resistor R6 to be connected to the source via 312 using the metal conductor 324 without the need for a transmission line crossing under (or over) the gate bus 316. In this regard, the third layout option may reduce or eliminate undesired oscillations from occurring at higher frequencies.

The values of the resistor R and capacitor C in the shunt RC network will be a function of the desired cutoff frequency of operation of the FET circuit. The cutoff frequency, f_{C}, of the shunt RC network may be determined using the following expression:

$${f}_{C} = \frac{1}{2 π R C} , \qquad ( 1 )$$

where R represents the resistance value (in ohms) and C represents the capacitance value (in farads) of the shunt RC network. For example, from equation (1) above, for a desired cutoff frequency f_{C} of about 790 MHz, the shunt RC network may employ a resistance of about 6.7 ohms (Ω) and a capacitance of about 30 picofarads (pF). The respective dimensions (in terms of layout area on the IC die 204) of the resistor R and capacitor C in the shunt RC network required to achieve a prescribed cutoff frequency will depend, at least in part, on the particular characteristics of the IC fabrication technology employed, which will specify certain electrical parameters associated with the IC die 204, such as, for example, sheet resistance, among other parameters.

The shunt RC network will configure the FET circuit to be unconditionally stable at a lower frequency by reducing the overall gain of the FET device. However, the extent of the gain reduction necessary to achieve a prescribed frequency stabilization result obtained by integrating the shunt RC network with the FET device will be less compared to using conventional off-chip frequency stabilization techniques (e.g., on a PCB). In other words, by integrating the shunt RC network closer to the active region 311 of the FET device, less gain reduction is required in order to stabilize the FET device to a prescribed frequency value.

The respective values of the resistor R and capacitor C in the integrated shunt RC network (e.g., 202 in FIG. 2A) may be selectively modified to satisfy prescribed requirements of different design applications. For example, for certain higher frequency applications (e.g., about 800 MHz or above), the FET device may not require unconditional stability at lower frequencies (e.g., about 200 MHz or less). In such embodiments, the shunt RC network may be configured having a higher cutoff frequency f_{C}, thereby increasing the maximum available gain G_{MAX} of the FET device (since G_{MAX} is inversely proportional to f_{C} of the shunt RC network).

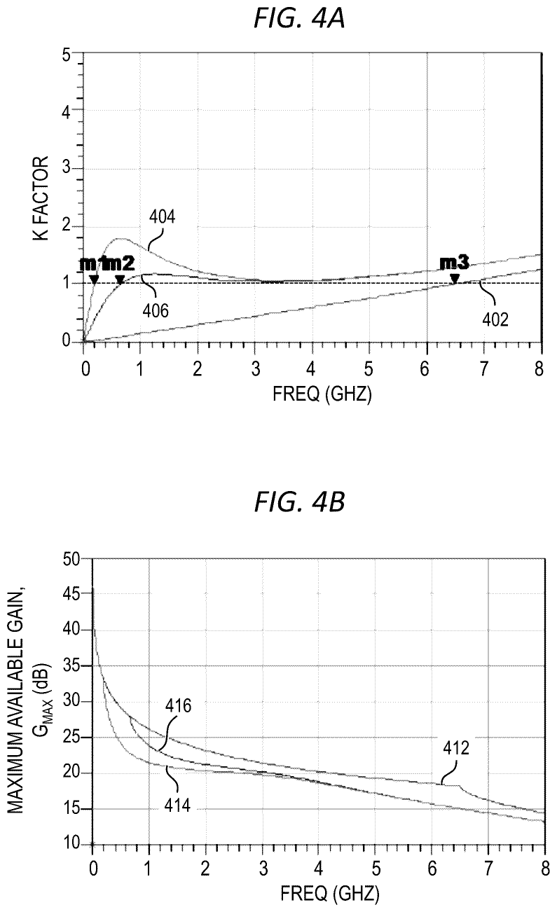

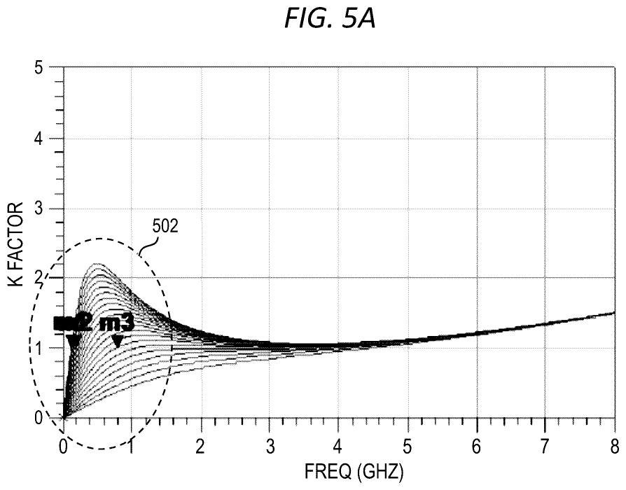

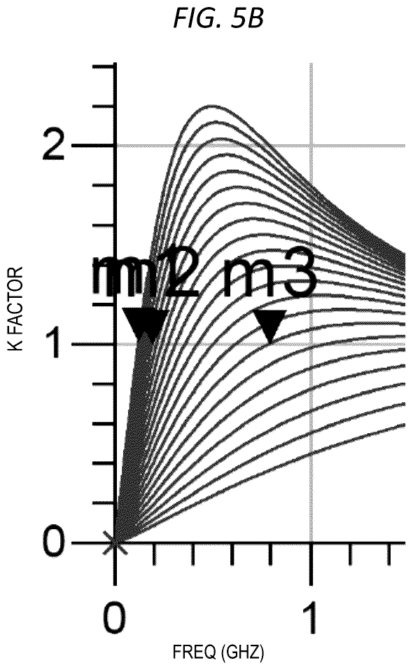

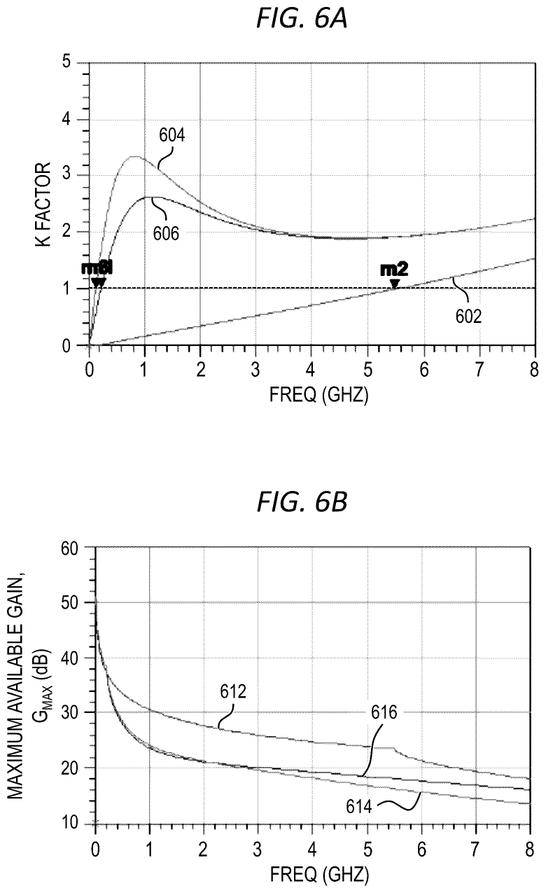

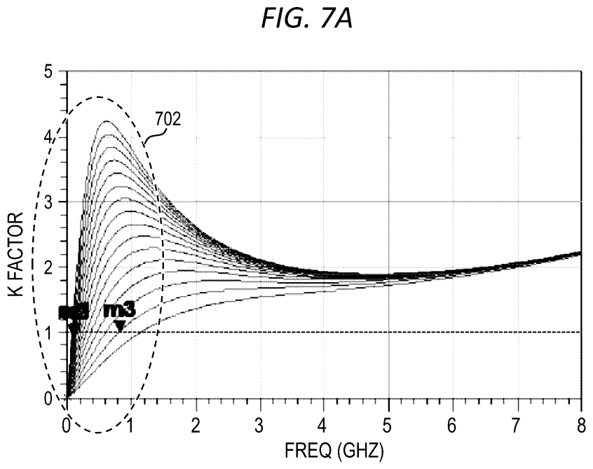

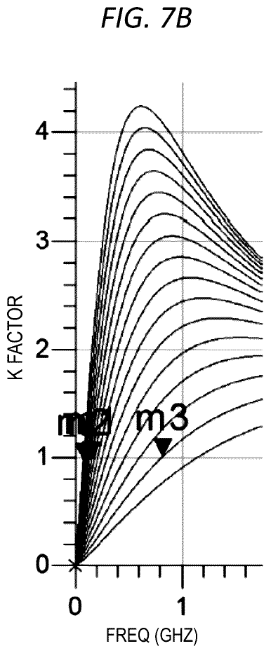

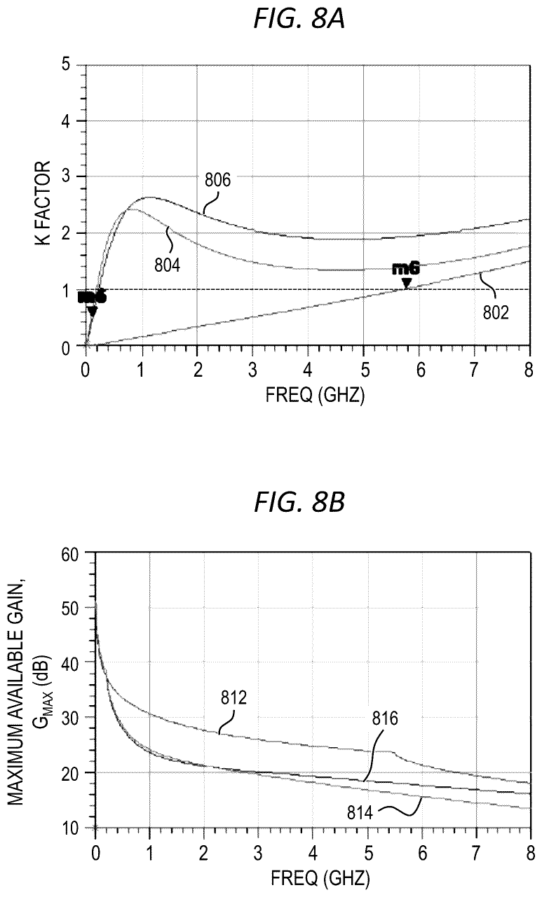

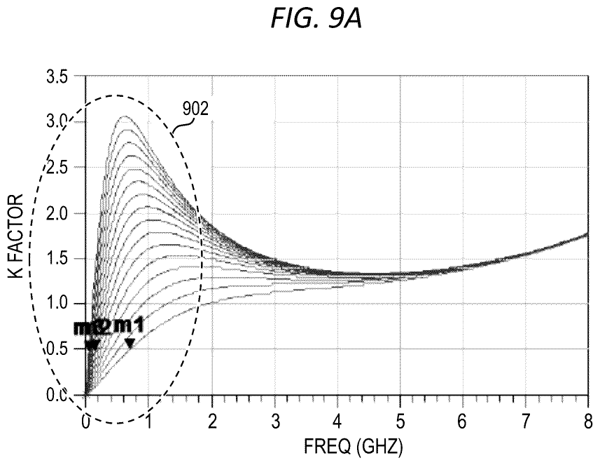

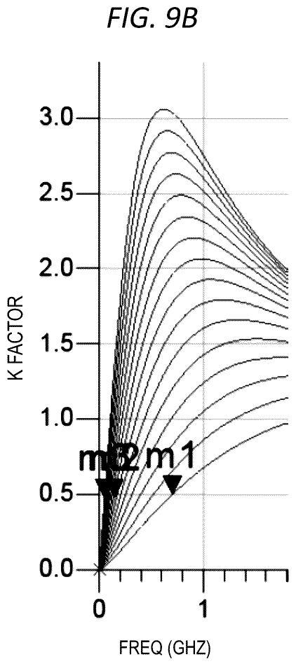

By way of example only and without limitation, FIGS. 4A, 4B, 5A, 5B, 6A, 6B, 7A, 7B, 8A, 8B, 9A and 9B are graphs conceptually illustrating configurations of the integrated shunt RC network configured to meet prescribed frequency stability requirements for different IC fabrication technologies, according to embodiments of the inventive concept. Specifically, FIGS. 4A and 4B depict stability and maximum available gain of the FET device using two different capacitance values in the shunt RC network compared to the FET device without the shunt RC network for a first IC fabrication technology (e.g., G28V5-1C process), and FIGS. 5A and 5B depict the effect of varying the capacitance value of the shunt RC network on stability of the FET device for the first IC fabrication technology. FIGS. 6A and 6B depict stability and maximum available gain of the FET device using two different capacitance values in the shunt RC network compared to the FET device without the shunt RC network for a second IC fabrication technology (e.g., G50V3-1C process), and FIGS. 7A and 7B depict the effect of varying the capacitance value of the shunt RC network on stability of the FET device for the second IC fabrication technology. FIGS. 8A and 8B depict stability and maximum available gain of the FET device using two different capacitance values in the shunt RC network compared to the FET device without the shunt RC network for a third IC fabrication technology (e.g., G50V4-1C process), and FIGS. 9A and 9B depict the effect of varying the capacitance value of the shunt RC network on stability of the FET device for the third IC fabrication technology.

An illustrative comparison between certain electrical characteristics associated with the first, second and third IC fabrication technologies are the shown in Table 1 below.

TABLE 1

| Process | | | | | | |
|---|---|---|---|---|---|---|
| Technology | G28V5-1C | | G50V3-1C | | G50V4-1C | |
| Gate Length | 0.15 | μm | 0.4 | μm | 0.25 | μm |
| Bias Voltage | 28 | V | 50 | V | 50 | V |
| Breakdown | >84 | V | >150 | V | >150 | V |
| Voltage | | | | | | |
| RF Density | 3.75 | W/mm | 8 | W/mm | 8.5 | W/mm |
| Frequency | DC-40 | GHz | DC-6 | GHz | DC-18 | GHz |
| Band | | | | | | |
| Substrate | 75 | μm | 100 | μm | 100 | μm |
| Thickness | | | | | | |

The electrical characteristics of the different illustrative IC fabrication technologies depicted in Table 1 above may affect the frequency stability of the FET device, and therefore the capacitance value required to achieve prescribed frequency stability parameters of the FET device may be configured (i.e., “tuned”) accordingly. For each of the simulations used in FIGS. 4A through 9B, a 3.6 mm die was used for the FET device, a 6.7-ohm resistor was used for the shunt RC network, and the capacitance of the shunt RC network was varied accordingly to tune the cutoff frequency of the shunt RC network for controlling a frequency at which the FET device is unconditionally stable.

Although the resistor in the shunt RC network was kept constant at 6.7 ohms for the simulations presented in FIGS. 4A through 9B, it is to be understood that in some embodiments, the capacitance of the shunt RC network may be kept constant and the resistance of the shunt RC network may be varied accordingly, or both the capacitance and resistance of the shunt RC network may be varied to meet prescribed frequency stability parameters.

In FIGS. 4A, 5A, 5B, 6A, 7A, 7B, 8A, 9A and 9B, K factor (i.e., stability factor) of the FET device is depicted as a function of frequency for the three different illustrative IC fabrication technologies, according to example embodiments of the inventive concept. The term “K factor” (or “stability factor”), as used in the context of a FET device, generally represents the relationship between the transistor's transconductance (gm) and its physical parameters, such as channel width (W) and length (L), essentially indicating how much current change occurs per unit change in gate voltage for a specific device geometry. When the K factor of the FET device is less than one, oscillation in the FET device may occur under certain operating conditions (e.g., certain load conditions). Conversely, when the K factor of the FET device exceeds one, it indicates that the FET device is unconditionally stable, meaning the circuit will be stable under all linear operating conditions with essentially no risk of unwanted oscillations at either the input or output ports of the circuit. In FIGS. 4B, 6B and 8B, maximum available gain G_{MAX} of the FET device is shown as a function of frequency for the different illustrative IC fabrication technologies, according to example embodiments of the inventive concept.

The three illustrative IC fabrication technologies (e.g., G28V5-1C, G50V3-1C and G50V4-1C) are presented herein merely as a means of showing how the capacitance of the shunt RC network may be tuned (while keeping the resistance constant, in the examples shown) to accommodate different IC fabrication technologies and to meet different prescribed operating parameters for the FET device (e.g., stability factor, etc.). It is to be appreciated, however, that the inventive concept is not limited to these fabrication technologies or to any specific values of resistance and/or capacitance of the shunt RC network.

Referring to FIG. 4A, for the first fabrication technology (G28V5-1C), waveform 402 represents the bare die FET device without a shunt RC network, waveform 404 represents the FET device including an integrated shunt RC network having a capacitance of about 40 pF, and waveform 406 represents the FET device including an integrated shunt RC network having a capacitance of about 23.5 pF. As shown in FIG. 4A, without any shunt RC network the FET device is not unconditionally stable for operating frequencies below about 6.5 GHz. Using a shunt RC network having a capacitance of about 40 pF, the FET device is unconditionally stable for operating frequencies down to about 190 MHz (waveform 404), and for a capacitance of about 23.5 pF, the FET device is unconditionally stable down to operating frequencies of about 640 MHz (waveform 406).

A MIM capacitor of about 23.5 pF disposed under the bond pad (e.g., bond pad 314 in FIG. 3) may be obtained for the first fabrication technology using bond pad dimensions of 528 μm×146 μm, which will provide unconditional stability of the FET device down to about 640 MHz. To obtain a higher capacitance value, one or more dimensions of the bond pad may be increased (to thereby increase an area of the bond pad), to the extent that there is sufficient space available on the IC die. For example, an increased bond pad size of 900 μm×146 μm may provide a capacitance of about 40 pF, which may be sufficient to allow the FET device to be unconditionally stable down to about 190 MHz, as previously stated.

FIG. 4B conceptually illustrates an effect of the shunt RC network capacitance on maximum available gain of the FET device for the first fabrication technology (G28V5-1C). Waveform 412 indicates maximum available gain of the FET device without any shunt RC network, waveform 414 indicates maximum available gain of the FET device with a shunt RC network having a capacitance of about 40 pF, and waveform 416 indicates maximum available gain of the FET device with a shunt RC network having a capacitance of about 23.5 pF. As shown in FIG. 4B, there is a slight decrease in maximum available gain of the FET device as a tradeoff for a lower frequency of unconditional stability of the FET device. For example, without any shunt RC network (waveform 412), the FET device has a maximum available gain of about 26 dB at 1 GHz, compared to a maximum available gain of about 23.75 dB for a shunt RC network having a capacitance of about 23.5 pF (waveform 416) or a maximum available gain of about 21.5 dB for a shunt RC network having a capacitance of about 40 pF (waveform 414). Thus, for applications that do not require unconditional frequency stability as low as 190 MHz, a lower value of capacitance may be used for the shunt RC network, thereby providing a higher maximum available gain. For applications above about 3.5 GHz, there is no significant difference in maximum available gain for capacitance values of about 23.5 pF or higher.

FIG. 5A conceptually illustrates the effect of varying the capacitance of the shunt RC network (while keeping the resistance of the shunt RC network constant at 6.7 ohms) on the K factor of the FET device, according to one or more embodiments. FIG. 5B is a graph depicting an enlarged portion, region 502, of the graph shown in FIG. 5A. Referring to FIGS. 5A and 5B, data point m1 indicates that the FET device has a K factor of about one (i.e., is unconditionally stable) at a frequency of 120 MHz using a capacitance of 50 pF for the shunt RC network, data point m2 indicates that the FET device has a K factor of about one at a frequency of 190 MHz using a capacitance of 40 pF for the shunt RC network, and data point m3 indicates that the FET device has a K factor of about one at a frequency of 790 MHz using a capacitance of 22 pF for the shunt RC network. As apparent from FIGS. 5A and 5B, as the capacitance of the shunt RC network decreases, the frequency at which the FET device is unconditionally stable increases. For capacitance values greater than about 40 pF, there is a minimal return in stability of the FET device, and for capacitance values less than about 20 pF, there is minimal benefit for lower frequency applications.

Referring now to FIG. 6A, for the second fabrication technology (G50V3-1C), waveform 602 represents the bare die FET device without a shunt RC network, waveform 604 represents the FET device including an integrated shunt RC network having a capacitance of about 30 pF, and waveform 606 represents the FET device including an integrated shunt RC network having a capacitance of about 27.5 pF. As shown in FIG. 6A, without any shunt RC network the FET device is not unconditionally stable for operating frequencies below about 5.58 GHz. Using a shunt RC network having a capacitance of about 30 pF (waveform 604), the FET device is unconditionally stable for operating frequencies down to about 130 MHz, and for a capacitance of about 27.5 pF (waveform 606), the FET device is unconditionally stable down to operating frequencies of about 230 MHz.

A MIM capacitor of about 23.5 pF disposed under the bond pad (e.g., bond pad 314 in FIG. 3) may be obtained for the second fabrication technology using bond pad dimensions of 528 μm×146 μm, which will provide unconditional stability of the FET device down to about 690 MHz. To obtain a higher capacitance value, one or more dimensions of the bond pad may be increased, to the extent that there is sufficient space available on the IC die. For example, an increased bond pad size of 700 μm×146 μm may provide a capacitance of about 31 pF, which may be sufficient to allow the FET device to be unconditionally stable down to about 90 MHz.

FIG. 6B conceptually illustrates an effect of the shunt RC network capacitance on maximum available gain of the FET device for the second fabrication technology (G50V3-1C). Waveform 612 indicates maximum available gain of the FET device without any shunt RC network, waveform 614 indicates maximum available gain of the FET device with a shunt RC network having a capacitance of about 30 pF, and waveform 616 indicates maximum available gain of the FET device with a shunt RC network having a capacitance of about 27.5 pF. As shown in FIG. 6B, there is a slight decrease in maximum available gain of the FET device as a tradeoff for a lower frequency of unconditional stability of the FET device. For operating frequencies below about 2.8 GHz, there is no significant difference in the reduction of maximum available gain between waveforms 614 and 616. For frequencies above about 2.8 GHz, using a capacitance of about 27.5 pF for the shunt RC network provides slightly more maximum available gain compared to using a capacitance of 30 pF. Without any shunt RC network (waveform 612), the FET device has a maximum available gain of about 30.5 dB at 1 GHz, compared to a maximum available gain of about 24 dB for a shunt RC network having a capacitance of about 30 pF (waveform 614) or a capacitance of about 27.5 pF (waveform 616).

FIG. 7A conceptually illustrates an effect of varying the capacitance of the shunt RC network (while keeping the resistance of the shunt RC network constant at 6.7 ohms) on K factor of the FET device, according to one or more embodiments. FIG. 7B is a graph depicting an enlarged portion, region 702, of the graph shown in FIG. 7A. Referring to FIGS. 7A and 7B, data point m1 indicates that the FET device has a K factor of one (i.e., is unconditionally stable) at a frequency of 130 MHz using a capacitance of 30 pF for the shunt RC network, data point m2 indicates that the FET device has a K factor of one at a frequency of 80 MHz using a capacitance of 38 pF for the shunt RC network, and data point m3 indicates that the FET device has a K factor of one at a frequency of 820 MHz using a capacitance of 12 pF for the shunt RC network. As apparent from FIGS. 7A and 7B, as the capacitance of the shunt RC network decreases, the frequency at which the FET device is unconditionally stable increases. For capacitance values greater than about 30 pF, there is a minimal return in stability of the FET device, and for capacitance values less than about 12 pF, there is minimal benefit for lower frequency applications.

Referring to FIG. 8A, for the third fabrication technology (G50V4-1C), waveform 802 represents the bare die FET device without a shunt RC network, waveform 804 represents the FET device including an integrated shunt RC network having a capacitance of about 31 pF, and waveform 806 represents the FET device including an integrated shunt RC network having a capacitance of about 23.5 pF. As shown in FIG. 8A, without any shunt RC network the FET device is not unconditionally stable for operating frequencies below about 5.77 GHz. Using a shunt RC network having a capacitance of about 31 pF, the FET device is unconditionally stable for operating frequencies down to about 90 MHz (waveform 804), and for a capacitance of about 23.5 pF, the FET device is unconditionally stable down to operating frequencies of about 110 MHz (waveform 806).

A MIM capacitor of about 23.5 pF disposed under the bond pad (e.g., bond pad 314 in FIG. 3) may be obtained for the third fabrication technology using bond pad dimensions of 528 μm×146 μm, which will provide unconditional stability of the FET device down to about 110 MHz. To obtain a higher capacitance value, one or more dimensions of the bond pad may be increased, to the extent that there is sufficient space available on the IC die. For example, an increased bond pad size of 700 μm×146 μm may provide a capacitance of about 31 pF, which may be sufficient to allow the FET device to be unconditionally stable down to about 90 MHz.

FIG. 8B conceptually illustrates an effect of the shunt RC network capacitance on maximum available gain of the FET device for the third fabrication technology (G50V4-1C). Waveform 812 indicates maximum available gain of the FET device without any shunt RC network, waveform 814 indicates maximum available gain of the FET device with a shunt RC network having a capacitance of about 31 pF, and waveform 816 indicates maximum available gain of the FET device with a shunt RC network having a capacitance of about 23.5 pF. As shown in FIG. 8B, there is a decrease in maximum available gain of the FET device as a tradeoff for a lower frequency of unconditional stability of the FET device. For example, without any shunt RC network (waveform 812), the FET device has a maximum available gain of about 31 dB at 1 GHz, compared to a maximum available gain of about 24 dB for a shunt RC network having a capacitance of about 23.5 pF (waveform 816) or a maximum available gain of about 23.75 dB for a shunt RC network having a capacitance of about 31 pF (waveform 814).

Differences in maximum available gain between the FET device without the shunt RC network and with the shunt RC network using capacitance values of 31 pF and 23.5 pF closely track one another for frequencies below about 200 MHz; above 200 MHz, the shunt RC network may cause the FET device to exhibit a more noticeable reduction in maximum available gain. For operating frequencies below about 3 GHZ, there is no significant difference in the reduction of maximum available gain between waveforms 814 and 816; above 3 GHZ, the higher capacitance (about 31 pF) of the shunt RC network represented by waveform 814 may further reduce the maximum available gain of the FET device compared to the capacitance (about 23.5 pF) of the shunt RC network represented by waveform 816.

FIG. 9A conceptually illustrates an effect of varying the capacitance of the shunt RC network (while keeping the resistance of the shunt RC network constant at 6.7 ohms) on K factor of the FET device, according to one or more embodiments. FIG. 9B is graph depicting an enlarged portion, region 902, of the graph shown in FIG. 9A. Referring to FIGS. 9A and 9B, data point m1 indicates that the FET device has a K factor of about one (i.e., is unconditionally stable) at a frequency of 700 MHz using a capacitance of 10 pF for the shunt RC network, data point m2 indicates that the FET device has a K factor of about one at a frequency of 140 MHz using a capacitance of 24 pF for the shunt RC network, and data point m3 indicates that the FET device has a K factor of about one at a frequency of 50 MHz using a capacitance of 40 pF for the shunt RC network. As apparent from FIGS. 9A and 9B, as the capacitance of the shunt RC network decreases, the frequency at which the FET device is unconditionally stable increases. For capacitance values greater than about 24 pF, there is a minimal return in stability of the FET device, and for capacitance values less than about 10 pF, there is minimal benefit for lower frequency applications.

It will be understood that although ordinal terms, such as first, second, etc., may be used herein to describe various elements, these elements should not be limited by such terms. These terms are only used to distinguish one element from another. For example, a first element could be termed a second element, and, similarly, a second element could be termed a first element, without departing from the scope of the present disclosure.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” as may be used herein, are intended to specify the presence of stated features, integers, steps, operations, elements, and/or components, but do not necessarily preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the present disclosure belongs. It will be further understood that terms used herein should be interpreted as having a meaning that is consistent with their meaning in the context of the present disclosure and the relevant art and will not be interpreted in an idealized or overly formal sense unless expressly so defined herein.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present.

Relative terms such as “below,” “above,” “upper,” “lower,” “horizontal,” “lateral,” and/or “vertical,” may be used herein to describe a relationship of one element, layer or region to another element, layer or region as illustrated in the figures. It will be understood, however, that these terms are intended to encompass different orientations of the device in place of or in addition to the orientation depicted in the figures.

In the drawings and specification, there have been disclosed illustrative embodiments of the invention and, although specific terms are employed, they are used in a generic and descriptive sense only and not for purposes of limitation, the scope of the invention being set forth in the following claims.

What is claimed is:

1. A transistor circuit, comprising:
a field-effect transistor (FET) device including a gate connected to an input terminal of the transistor circuit, a source connected to a reference voltage of the transistor circuit, and a drain connected to an output terminal of the transistor circuit; and
a shunt resistor-capacitor (RC) network connected in series between the gate of the FET device and the reference voltage of the transistor circuit,
wherein the shunt RC network is integrated on a same die with the FET device.

2. The transistor circuit of claim 1, further comprising at least one bond pad connected to the gate of the FET device, wherein a capacitor in the shunt RC network is disposed under the at least one bond pad.

3. The transistor circuit of claim 2, wherein the at least one bond pad forms an electrode of the capacitor in the shunt RC network.

4. The transistor circuit of claim 1, further comprising at least one bond pad connected to the gate of the FET device,
wherein the shunt RC network comprises a resistor and a capacitor, a first terminal of the resistor is connected to the reference voltage of the transistor circuit through at least one of a source via of the FET device or an independent via, a second terminal of the resistor is connected to a first terminal of the capacitor, and a second terminal of the capacitor is connected to the at least one bond pad.

5. The transistor circuit of claim 1, wherein the FET device and the shunt RC network are disposed on a Group III nitride semiconductor layer structure.

6. The transistor circuit of claim 1, wherein the FET device comprises a plurality of unit cells, the plurality of unit cells comprising a respective plurality of bond pads, wherein at least a resistor in the shunt RC network is disposed between an adjacent pair of bond pads of the plurality of bond pads.

7. The transistor circuit of claim 1, wherein the FET device comprises a plurality of fingers, each of the plurality of fingers comprising a source and a source via connecting the source to the reference voltage of the transistor circuit, and wherein the shunt RC network comprises a plurality of resistors, each of the plurality of resistors is connected to the reference voltage of the transistor circuit through the source via of a corresponding one of the plurality of fingers of the FET device.

8. The transistor circuit of claim 7, wherein each of the plurality of resistors is disposed between a corresponding one of the sources of the plurality of fingers of the FET device and the at least one bond pad.

9. An integrated circuit (IC) die, comprising:
a field-effect transistor (FET) including a gate configured to receive an input signal provided to the FET, a source connected to a reference voltage through a source via, and a drain configured to present an output signal of the FET; and
a shunt resistor-capacitor (RC) network connected between the gate of the FET and the reference voltage through the source via.

10. The IC die of claim 9, further comprising at least one bond pad connected to the gate of the FET, wherein a capacitor in the shunt RC network is disposed under the at least one bond pad.

11. The IC die of claim 10, wherein the capacitor in the shunt RC network comprises a first electrode, a second electrode and a dielectric material between the first and second electrodes, and wherein the at least one bond pad forms the first electrode of the capacitor in the shunt RC network.

12. The IC die of claim 9, further comprising a bond pad connected to the gate of the FET, wherein the shunt RC network comprises a resistor and a capacitor, a first terminal of the resistor is connected to the reference voltage through the source via of the FET, a second terminal of the resistor is connected to a first terminal of the capacitor, and a second terminal of the capacitor is connected to the bond pad.

13. The IC die of claim 9, wherein the FET comprises a plurality of fingers, each of the plurality of fingers comprising a source and a source via connecting the source to the reference voltage, and wherein the shunt RC network comprises a plurality of resistors, each of the plurality of resistors is connected to the reference voltage through the source via of a corresponding one of the plurality of fingers of the FET.

14. The IC die of claim 9, wherein the FET comprises a plurality of unit cells, the plurality of unit cells comprising a respective plurality of bond pads, wherein the shunt RC network comprises at least one resistor disposed between a pair of adjacent bond pads of the plurality of bond pads.

15. An integrated circuit (IC) die, comprising:
at least one bond pad;
a field-effect transistor (FET) including a gate connected to the at least one bond pad, a source connected to a reference voltage through a source via, and a drain; and
a shunt resistor-capacitor (RC) network connected between the gate of the FET and the reference voltage,
wherein the shunt RC network comprises a first capacitor including a first electrode, a second electrode and a dielectric material between the first and second electrodes, and wherein the at least one bond pad forms the first electrode of the first capacitor in the shunt RC network.

16. The IC die of claim 15, wherein the FET comprises a plurality of fingers, each of the plurality of fingers comprising a source and a source via connecting the source to the reference voltage, and wherein the shunt RC network comprises a plurality of resistors, each of the plurality of resistors is connected to the reference voltage through the source via of a corresponding one of the plurality of fingers of the FET.

17. The IC die of claim 15, wherein the FET comprises a plurality of unit cells, the plurality of unit cells comprising a respective plurality of bond pads, wherein the shunt RC network comprises at least one resistor connected in series with the first capacitor and disposed between a pair of an adjacent bond pads of the plurality of bond pads.

18. The IC die of claim 15, wherein the FET comprises a plurality of unit cells, the plurality of unit cells comprising a respective plurality of bond pads, and wherein the first capacitor comprises a plurality of capacitors, each of the plurality of capacitors disposed under a corresponding one of the plurality of bond pads, each of the plurality of bond pads forming an electrode of a corresponding one of the plurality of capacitors.

19. The IC die of claim 15, wherein the shunt RC network comprises a resistor and a second capacitor, the second capacitor is connected in series between the resistor and the reference voltage.

20. The IC die of claim 15, wherein the shunt RC network comprises a resistor, a first terminal of the resistor is connected to the reference voltage of the transistor circuit through at least one of the source via of the FET or an independent via, and a second terminal of the resistor is connected to the second electrode of the first capacitor.
